(19) United States
(12) Patent Application Publication
(10) Pub. No.: US 2005/0078294 A1
(43) Pub. Date: Apr. 14, 2005

(54) Method of forming optical images, diffration element for use with this method, apparatus for carrying out this method

(76) Inventor: Antonius Johannes Maria Nellissen, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/499,257

(22) PCT Filed: Dec. 11, 2002
(86) PCT No.: PCT/IB02/05342

(30) Foreign Application Priority Data
Dec. 17, 2001 (EP) 012049334

(51) Int. Cl. G03B 27/00; G03F 7/00

(52) U.S. Cl. 355/77; 430/322; 355/18

(57) ABSTRACT

An optical image is formed in a resist layer (5) by a number of sub-illuminations, in each of which an array of light valves (21-25) and a corresponding array of diffraction cells (91-95) are used to form a pattern of spots (111-115) in the resist layer according to a sub-image. Between the sub-illuminations, the resist layer is displaced relative to the arrays. Bright and well-defined spots are obtained by using diffraction cells having at least two amplitude levels and at least three phase levels.

The invention relates to a method of forming an optical image in a resist layer, the method comprising the steps of:
providing a source of optical radiation;
providing a resist layer;
positioning a two-dimensional array of individually controlled light valves between the radiation source and the resist layer;
positioning a two-dimensional array of diffraction lenses between the array of light valves and the resist layer, such that each diffraction lens corresponds to a different one of the light valves;
successively illuminating different portions of the resist layer by means of successive sub-illuminations, each sub-illumination comprising the steps of switching on a selection of the light valves, switching on the radiation source, switching off the light valves and the radiation source and displacing the resist layer and the arrays relative to each other so that a subsequent layer portion to be illuminated is aligned with the arrays.

The invention also relates to a diffraction element comprising an array of diffraction cells for use with this method, an apparatus for carrying out this method and a method of manufacturing a device using this method.

An array of light valves, or optical shutters, is understood to mean an array of controllable elements, which can be switched between two states. In one of the states, radiation incident on such an element is blocked and, in the other states, the incident radiation is transmitted or reflected to follow a path that is prescribed in the apparatus of which the array forms part.

Such an array may be a transmissive or reflective liquid crystal display (LCD) or a digital mirror device (DMD). A resist layer is a layer of material, which is sensitive to radiation used in optical lithography.

This method and apparatus may be used, inter alia, in the manufacture of devices such as liquid crystalline display (LCD) panels, customized ICs (integrated circuits) and PCBs (printed circuit board). Currently, proximity printing is used in the manufacture of such devices. Proximity printing is a fast and cheap method of forming an image in a radiation-sensitive layer on a substrate of the device, which image comprises features corresponding to device features to be configured in a layer of the substrate. Use is made of a large photo mask that is arranged at a short distance, called the proximity gap, from the substrate and the substrate is illuminated via the photo mask by, for example, ultraviolet (UV) radiation. An important advantage of the method is the large image field, so that large device patterns can be imaged in one image step. The pattern of a conventional photo mask for proximity printing is a true, one-to-one copy, of the image required on the substrate, i.e. each picture element (pixel) of this image is identical to the corresponding pixel in the mask pattern.

Proximity printing has a limited resolution, i.e. the ability to reproduce the points, lines etc., in general the features, in the mask pattern as separate entities in the sensitive layer on the substrate. This is due to the diffractive effects, which occur when the dimensions of the features decrease with respect to the wavelength of the radiation used for imaging. For example, for a wavelength in the near UV range and a proximity gap width of 100 μm, the resolution is 10 μm, which means that pattern features at a mutual distance of 10 sum can be imaged as separate elements.

To increase the resolution in optical lithography, a real projection apparatus, i.e. an apparatus having a real projection system like a lens projection system or a mirror projection system, are used. Examples of such apparatus are wafer steppers or wafer step-and scanners. In a wafer stepper, a whole mask pattern, for example an IC pattern is imaged at one go by a projection lens system on a first IC area of the substrate. Then the mask and substrate are moved (stepped) relative to each other until a second IC area is positioned below the projection lens. The mask pattern is then imaged on the second IC area. These steps are repeated until all IC areas of the substrate are provided with an image of the mask pattern. This is a time-consuming process, due to the sub-steps of moving, aligning and illumination. In a step-and-scanner, only a small portion of the mask pattern is illuminated at once. During illumination, the mask and the substrate are synchronously moved with respect to the illumination beam until the whole mask pattern has been illuminated and a complete image of this pattern has been formed on an IC area of the substrate. Then the mask and substrate are moved relative to each other until the next IC area is positioned under the projection lens and the mask pattern is again scan-illuminated, so that a complete image of the mask pattern is formed on the next IC area. These steps are repeated until all IC areas of the substrate are provided with a complete image of the mask pattern. The step-and-scanning process is even more time-consuming than the stepping process.

If a 1:1 stepper, i.e. a stepper with a magnification of one, is used to print a LCD pattern, a resolution of 3 μm can be obtained, however, at the expense of much time for imaging. Moreover, if the pattern is large and has to be divided into sub-patterns, which are imaged separately, stitching problems may occur, which means that neighboring sub-fields do not fit exactly together.

The manufacture of a photo mask is a time-consuming and cumbersome process, which renders such a mask expensive. If much re-design of a photo mask is necessary or in case customer-specific devices, i.e. a relative small number of the same device, have to be manufactured, the lithographic manufacturing method using a photo mask is an expensive method.

The paper: “Lithographic patterning and confocal imaging with zone plates” of D. Gil et al in: J. Vac. Sci. Technology B 18(6), November/December 2000, pages 2881-2885, describes a lithographic method wherein, instead of a photo mask, a combination of a DMD array and an array of zone plates is used. If the array of zone plates, also called Fresnel lenses, is illuminated, it produces an array of radiation spots, in the experiment described in the paper: an array of 3×3 X-ray spots, on a substrate. The spot size is approximately equal to the minimum feature size, i.e. the outer zone width, of the zone plate. The radiation to each zone plate is separately turned on and off by the micro-mechanic means of the DMD device and by raster scanning the substrate through a zone plate unit cell, arbitrary patterns can be written. In this way, the advantages of maskless lithography are combined with high throughput due to parallel writing with an array of spots. The zone plates of the array are conventional phase zone plates, i.e. they comprise alternating first rings and second rings all first rings and second rings being at a constant first level and a constant second level, respectively. Radiation passing through the first rings undergoes a phase shift of 180° relative to radiation passing through the second rings. In the paper it is remarked that order-sorting apertures are needed to reduce background radiation caused by non-focused diffraction orders.

It is an object of the present invention to provide an accurate and radiation-efficient lithographic imaging method. This method is characterized in that use is made of diffraction lenses in the form of diffraction cells having at least two transmission levels and at least three phase levels.

The diffraction cells are usually, but not necessarily identical. The amplitude level and the phase level of a diffraction cell are measures of the degree, to which a diffraction cell changes the amplitude and phase, respectively, of a beam portion incident on this cell. The phase level of an area of a diffraction cell is determined, for example, by the height or depth of this area with respect to the surface of the total array.

By using more than two phase levels per cell, the diffraction efficiency, i.e. the percentage of the incident radiation that is diffracted in the required diffraction order, for example a first order, increases. This means that the available radiation is optimally used for imaging in the resist layer and that the amount of background radiation, for example zero order, or non-diffracted, radiation is so small that this radiation needs no to be blocked by means of, for example, order filters.

The diffraction efficiency of the cells and the sharpness of the spots formed by these cells increase with the number of phase steps in the cells. Reasonable results can be obtained with a limited number of phase steps, for example four steps differing 90° from each other. Usually, two amplitude levels for each diffraction cell are sufficient. The main part of the cell is “white” and only the border of a cell is black to distinguish the cell from its neighboring cells. “White” means transmitting or reflecting incident radiation to the resist layer and “black” means preventing incident radiation from reaching this layer. The black portions of all diffraction cells may be constituted by one layer of, for example a metal such as chromium, which layer has relative wide openings to accommodate the white portions with the phase structure. Chromium is already widely used in optical lithography. The phase structures may be etched in the diffraction element of, for example, quartz by an ion beam technique.

A first embodiment of the method is characterized in that use is made of an array of diffraction cells each showing a series of rising phase steps and a series of declining phase steps.

A second embodiment of the method is characterized in that use is made of an array of diffraction cells each comprising a number of successive phase structures, each phase structure comprising a number of phase steps rising from a base level to a top level followed by a decline from the top level to the base level.

A third embodiment of the method is characterized in that use is made of an array of diffraction cell each comprising a number of successive phase structures, each phase structure showing a continuous increase from a base level to a top level and an abrupt decline from the top level to the base level.

These embodiments may be further characterized in that use is made of an array comprising collections of diffraction cells, which collections differ from each other in that the focal plane of the diffraction cells of each collection is different from the focal planes of the other collections.

This method allows printing on different planes of the substrate.

The method may be further characterized in that, between successive sub-illuminations, the radiation-sensitive layer and the arrays are displaced relative to each other through a distance which is at most equal to the size of the spots formed in the resist layer.

In this way, image, i.e. pattern, features can be written with a constant intensity across the whole feature. The spots may have a circular, square, diamond or rectangular shape, dependent on the design of the diffraction cells. The size of the spot is the size of the largest dimension within this spot.

If features of the image to be written are very close to each other, these features may broaden and merge with each other, which phenomenon is known as proximity effect. An embodiment of the method, which prevents proximity effects from occurring, is characterized in that the intensity of a spot at the border of an image feature is adapted to the distance between this feature border and a neighboring feature.

The method preferably is characterized in that the illumination step comprises illuminating the array with a beam of monochromatic radiation.

Monochromatic radiation has only one wavelength and is very suitable to be used with a diffraction element, the diffraction property of which is wavelength dependent. A laser may be used for generating the monochromatic radiation.

The method may be further characterized in that the array of light valves is positioned to directly face the array of diffraction cells.

The two arrays are positioned close to each other, without imaging means being arranged between them, so that the method can be performed by compact means. If the array of light valves is an array of LCD cells, which modulate the polarization of incident radiation, a polarization analyzer is arranged between the LCD and the array of diffraction cells.

Alternatively, the method may be characterized in that the array of light valves is imaged on the array of diffraction cells.

Imaging one array on the other by a projection lens provides advantages with respect to stability, thermal effects, and crosstalk

The invention also relates to a diffraction element for use with the method described above and comprising an array of diffraction cells. This diffraction element is characterized in that the diffraction cells have at lest two amplitude levels and at least three phase levels.

A relatively simple embodiment of the diffraction element is characterized in that each diffraction cell has a series of rising phase steps and a series of declining phase steps.

This embodiment may be further characterized in that the diffraction cells have four phase levels, which differ from each other by 90°.

Satisfactory results can be obtained with such a diffraction element.

Even better results are possible with an embodiment of the diffraction element which is characterized in that each diffraction cell comprises a number of successive phase structures, each phase structure comprising a number of phase steps rising from a base level to a top level followed by a decline from the top level to the base level.

An alternative embodiment of the diffraction element is characterized in that each diffraction cell comprises a number of successive phase structures, each phase structure showing a continuous increase from a base level to a top level and an abrupt decline from the top level to the base level.

This embodiment is less easy to manufacture than the preceding one, but provides the best results.

The diffraction element may be further characterized in that it comprises collections of diffraction cells, which collections differ from each other in that the focal plane of the diffraction cells of each collection is different from the focal planes of the other collections.

This diffraction element, which can be used if the spots to be formed in the resist layer are not very small, allows simultaneous imaging of pattern features at different heights in the resist layer so that time can be saved.

The invention also relates to an apparatus for carrying out the method described above. This apparatus comprises:
a radiation source;
a substrate holder for holding a substrate provided with a resist layer;
a two-dimensional array of individually controllable light valves arranged between the source and the substrate holder, and
a diffraction element comprising a two-dimensional array of diffraction lenses arranged between the array of light valves and the substrate holder, such that each diffraction lens corresponds to a different one of the light valves, and is characterized in that diffraction lenses are diffraction cells having at least two amplitude levels and at least three phase levels.

With this apparatus, arbitrary patterns can be written by scanning the resist layer with a number of sharp spots simultaneously, wherein efficient use is made of the available radiation.

A first embodiment of the apparatus is characterized in that each diffraction cell has a series of rising phase steps and a series of declining phase steps.

This embodiment may be further characterized in that the diffraction cells have four phase levels, which differ from each other by 90°.

Satisfactory results are obtained with such a diffraction element.

A second embodiment of the apparatus is characterized in that each diffraction cell comprises a number of successive phase structures, each phase structure comprising a number of phase steps rising from a base level to a top level followed by a decline from the top level to the base level.

Such a phase profile in each cell allows obtaining a maximum diffraction in one, required, order and maximum sharpness of the spots.

A third embodiment of the apparatus is characterized in that each diffraction cell comprises a number of successive phase structures, each phase structure showing a continuous increase from a base level to a top level and an abrupt decline from the top level to the base level.

All of the above embodiments may be further characterized in that the diffraction element comprises collections of diffraction cells, which collections differ from each other in that the focal plane of the diffraction cells of each collection is different from the focal planes of the other collections.

The apparatus is preferably characterized in that the radiation source is a source of monochromatic radiation.

Under circumstances, also other sources may be used such as a conventional mercury-arc lamp, which emits several wavelength bands.

The apparatus may be further characterized in that the diffraction element is arranged behind the array of light valves without intervening imaging means.

The gap, for example an air gap, may be very small so that this embodiment has a sandwich shape. If the array of light valves is a LCD, a polarization analyzer is arranged between the array of light valves and the array of diffraction cells.

An embodiment of the apparatus, which is alternative to the sandwich embodiment, is characterized in that a projection lens is arranged between the array of light valves and the diffraction element.

The projection lens images each light valve on its associated diffraction cell in the diffraction element so that crosstalk, optical aberrations and temperature effects are eliminated. Moreover, the substrate of the diffraction element may be relatively thick and thus the apparatus will be more stable.

The invention also relates to a method of manufacturing a device in at least one process layer of a substrate, the method comprising the steps of:
forming an image, comprising features corresponding to device features to be configured in the process layer, in a resist layer provided on the process layer, and
removing material from, or adding material to, areas of the process layer, which areas are delineated by the image formed in the resist layer. This method is characterized in that the image is formed by means of the method as described above.

Devices, which can be manufactured by means of this method and apparatus, are liquid crystalline display devices, customer-specific ICs, electronic modules, printed circuit boards etc. Examples of such devices are micro-optical-electrical-mechanical (MOEM) modules and integrated optical telecommunication devices comprising a diode laser and/or detector, a light guide and possibly a lens between the light guide and the diode laser, or the detector.

These and other aspects of the invention are apparent from and will be elucidated, by way of non-limitative example, with reference to the embodiments described hereinafter.

In the drawings:

FIG. 1 shows schematically a conventional proximity printing apparatus;

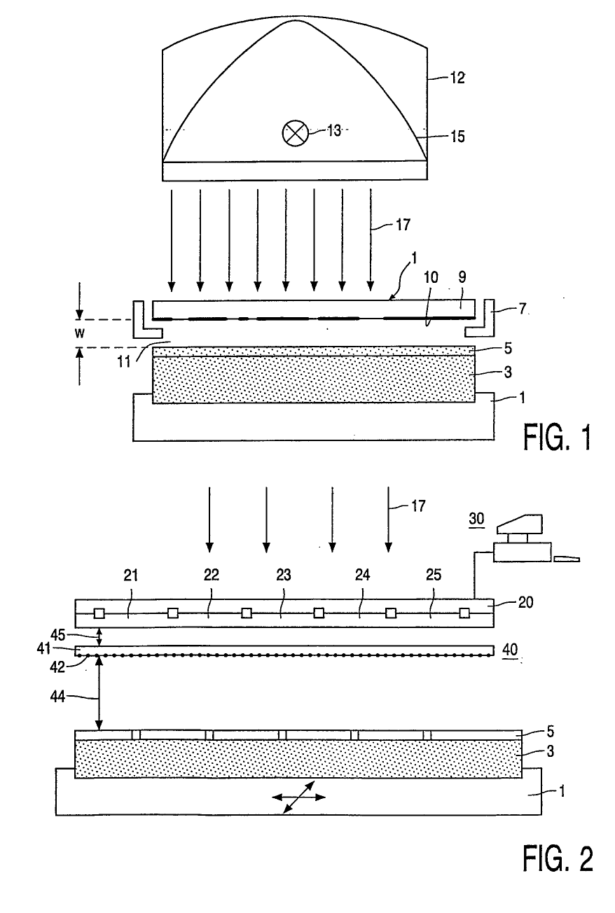

FIG. 2 shows an embodiment of an imaging apparatus according to the invention;

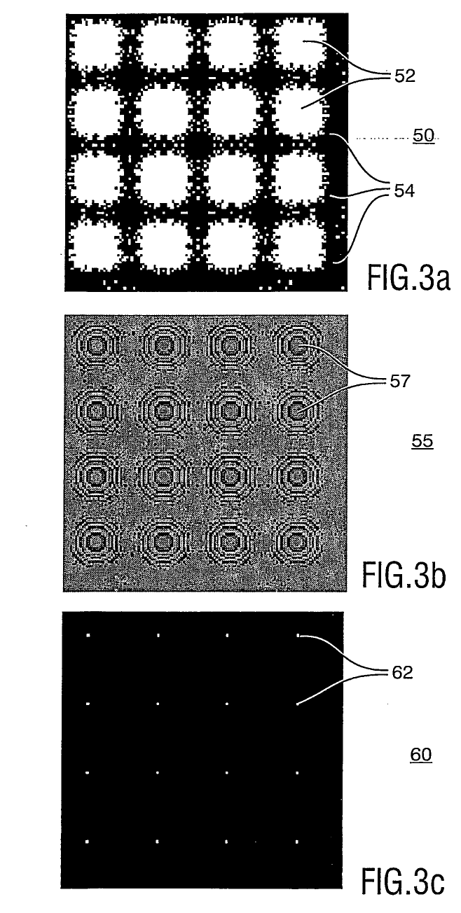

FIG. 3a shows the amplitude structure of a portion of an embodiment of the diffraction element according to the invention;

FIG. 3b shows the phase structure of this embodiment;

FIG. 3c shows the spots formed in the resist layer by means of this embodiment;

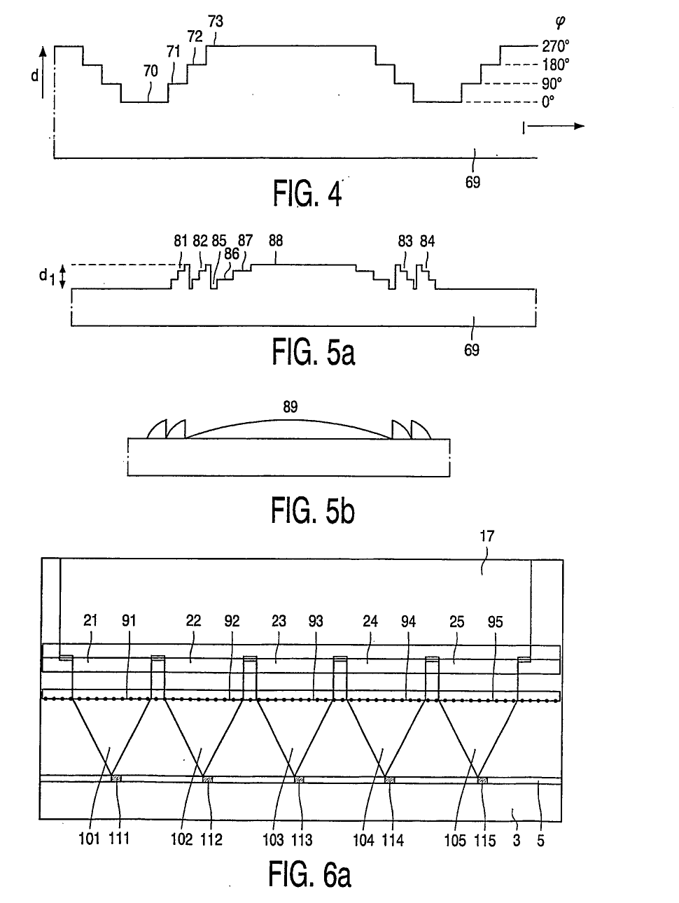

FIG. 4 shows a first embodiment of the depth structure of a diffraction element according to the invention;

IG. 5 shows a second embodiment of such a depth structure;

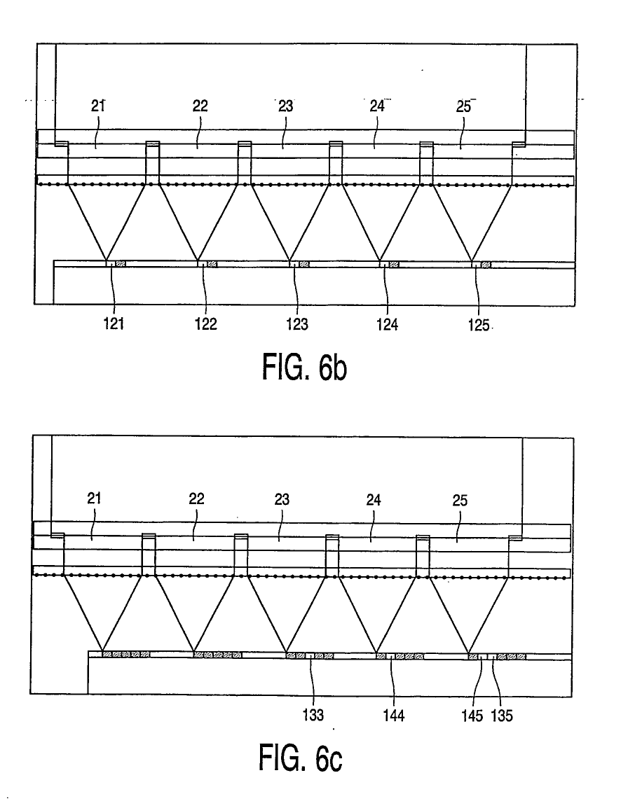

FIGS. 6a-6c show different moments of the printing process in a cross-section of the resist layer;

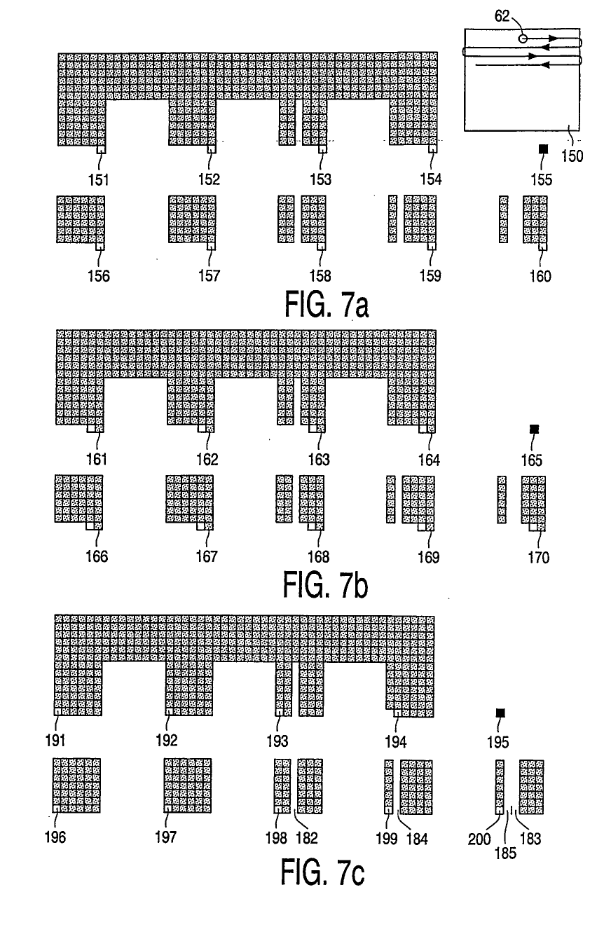

FIGS. 7a-7c show different moments of the printing process in a top view of the resist layer;

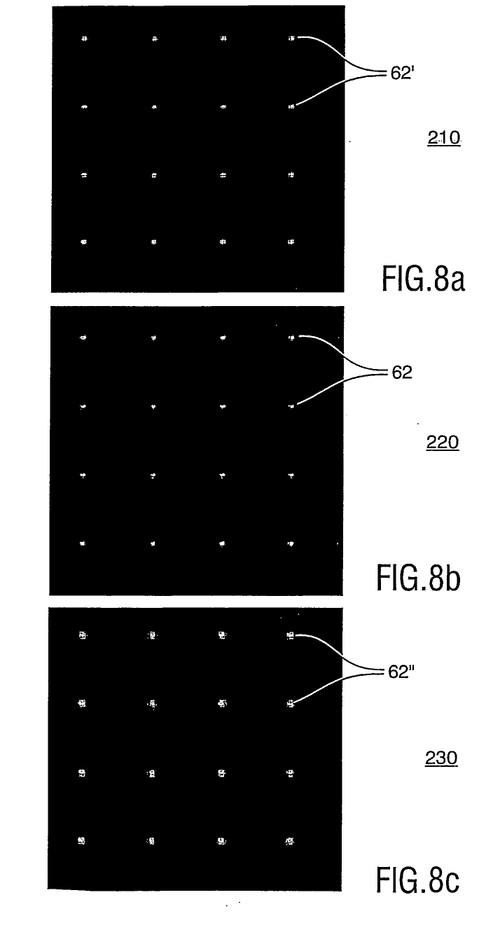

FIGS. 8a-8c show an array of spots formed with different widths of the gap between the diffraction element and the resist layer, and

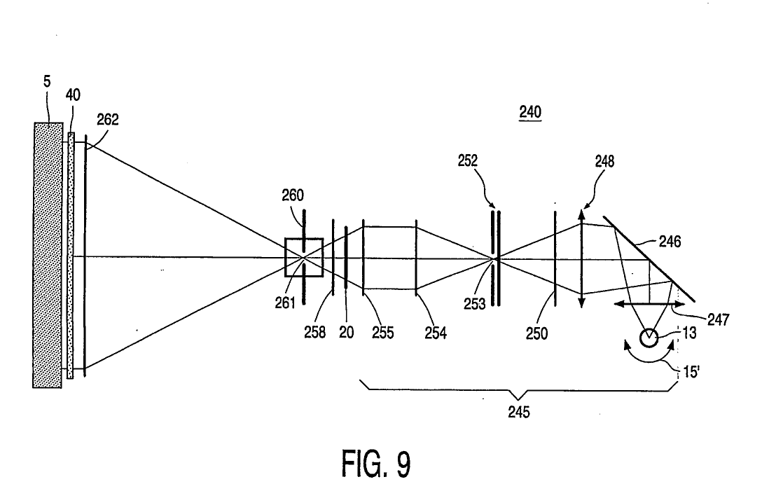

FIG. 9 shows an embodiment of the imaging apparatus including a projection lens between the array of light valves and the diffraction element.

FIG. 1 shows, very schematically, a conventional proximity printing apparatus for the manufacture of, for example a LCD device. This apparatus comprises a substrate holder 1 for carrying a substrate 3 on which the device is to be made. The substrate is coated with a radiation-sensitive, or resist, layer 5 in which an image having features corresponding to the device features is to be formed. The image information is contained in a mask 8 arranged in a mask holder 7. The mask comprises a transparent substrate 9, the lower surface of which is provided with a pattern 10 of transparent and non-transparent strips and areas, which represent the image information. A small air gap 11 having a gap width w of the order of 100 μm separates the pattern 10 from the resist layer 5. The apparatus further comprises a radiation source 12. This source may comprise a lamp 13, for example, a mercury arc lamp, and a reflector 15. This reflector reflects lamp radiation, which is emitted in backward and sideways directions towards the mask. The reflector may be a parabolic reflector and the lamp may be positioned in a focal point of the reflector, so that the radiation beam 17 from the radiation source is substantially a collimated beam. Other or additional optical elements, like one or more lenses, may be arranged in the radiation source to ensure that the beam 17 is substantially collimated. This beam is rather broad and illuminates the whole mask pattern 10 which may have dimensions from 7.5×7.5 cm² to 40×40 cm². An illumination step takes, for example, of the order of 10 seconds. After the mask pattern has been imaged in the resist layer, this is processed in the well-known way, i.e. the layer is developed and etched, so that the optical image is transferred in a surface structure of the substrate layer being processed.

The apparatus of FIG. 1 has a relatively simple construction and is very suitable for imaging at one go a large area mask pattern in the resist layer. However, the photo mask is an expensive component and the price of a device manufactured by means of such a mask can be kept reasonably low only if a large number of the same device is manufactured. Mask making is a specialized technology, which is in the hands of relatively few mask manufacturing firms. The time a device manufacturer needs to manufacture a new device or a modification of an existing device is strongly dependent on delivery times of the mask manufacture. Especially in the development phase of a device, when redesigns of the mask are often needed, the mask is a capability-limiting element. This is also the case for low-volume, customer-specific devices

Direct writing of a pattern in the resist layer, for example by an electron beam writer or a laser beam writer, could provide the required flexibility, but is not a real alternative because this process takes too much time.

FIG. 2 shows the principle of a maskless method and apparatus by means of which an arbitrary and easily changeable image pattern can be formed in a resist layer within a reasonable time. FIG. 2 shows very schematically and in a vertical cross-section a small portion of the means, which are used for performing the method and form part of the apparatus. The apparatus comprises a substrate holder 1 for accommodating a substrate, which is coated with a resist layer 5. Reference numeral 20 denotes a light valve device, for example a liquid crystal display (LCD), which is currently used for displaying information, either in direct-view or in projection. Device 20 comprises a large number of light valves, also called pixels (picture elements) of which only a few, 21 -26, are shown in FIG. 2. The light valve device is controlled by a computer configuration 30 wherein the pattern, which is to be configured in a substrate layer is introduced in software. The computer thus determines at any moment of the writing process and for every light valves whether it is open, i.e. blocks the portion of the illuminating beam 17 or transmits this portion to the resist layer. Arranged between the array of light valves 20 and the resist layer 5 is a diffraction element 40, which comprises a transparent substrate 41 and a diffraction structure 42. This diffraction structure is composed of a large number of diffraction cells, corresponding to the number of light valves. The array of diffraction cells is aligned with the array of light valves so that each diffraction cell belongs to a different one of the light valves.

As the radiation source, the substrate holder and the mask holder are less relevant for understanding the new method, these elements are not shown in FIG. 2.

According to the invention, the diffraction cells have two amplitude levels and four phase levels. FIG. 3a shows the amplitude structure 50 of sixteen of the cells and FIG. 3b shows their phase structure 55. The amplitude structure is a black and white structure; the central main portion 52 of each cell is white or transparent and transmits incident radiation and the border portion 54 of the cell is black or radiation-blocking. As shown in FIG. 3a, the border portion of a cell flows in the border portion of the neighboring cells. The border portions of all cells may be constituted by a radiation-absorbing or reflecting layer, which is provided with relatively large openings wherein the phase structure shown in FIG. 3b is accommodated. The cell phase structure 57 should introduce phase difference between sub-portions of the beam portion passing through the cell, such that constructive and destructive interference occurs in that beam portion, resulting in a small spot being formed in the resist layer. The use of diffraction cells allows adaptation of the shape of the spots to a required application. By adapting the contour lines of the phase structure in the cells, for example round, rectangular, square or diamond shaped-spots can be produced. The size of the spots in the resist layer is determined by the phase structure of the cell. The amplitude structure of the diffraction element is adapted to the geometric structure of the light valve array and the diffraction element is arranged at a distance from the array, such that as much as possible of the radiation from a light valve passes through the transparent portion 52 of the associated diffraction cells. The phase structure 57 of the diffraction cells is designed in such a way that a maximum amount of the radiation incident on a cell is concentrated in the spot produced by this cell and a minimum amount of background radiation occurs.

FIG. 3c shows the array 60 of spots 62 obtained by an embodiment, having four phase levels, of the diffraction structure of FIGS. 3a, 3b if the corresponding portion of the light valve array is illuminated with radiation having a wavelength of 365 nm, the distance 44 between the diffraction structure 42 and the resist layer 5 is 50 μm and all light valves are open. The spots 62 have a size of the order of 1 μm².

The phase structure of a diffraction cell may be any phase structure, which introduces the required phase differences in the associated beam portions. From a manufacturing point of view, the phase structure is preferably a depth, or level, structure.

FIG. 4 shows, in a vertical cross-section, an embodiment of such a depth structure for a four-phase level structure. FIG. 4 shows one of the diffraction cells and portions of two of its neighboring cells. The horizontal axis represents the length or width direction of the diffraction element, and the depth or height of the levels, relative to the surface of the cell, at a given position is plotted along the vertical axis. Each cell has four different geometrical levels 70-73, which introduce four different phase shifts φ of 0°, 9°, 180° and 270°, respectively. A phase shift of 360° has the same effect as a phase shift of 0°. Spots of good quality as shown in FIG. 3c can be obtained with a diffraction element having cells with such a phase structure.

FIG. 5a shows, also in a vertical cross-section, another, preferred embodiment of a diffraction cell with four phase levels. This cell has a relatively broad central portion 80 and two side portions 81,82 at the left side of the central portion and two side portions 83,84 at the right side of the central portion. All portions 80-84 have four different geometrical levels 85-88. If this diffraction cell has to produce a round spot, the area of level 88 of the central portion 80 is round and the areas of the levels 85-87 of the central portions and those of the side portions 81-84 are annular. The thickness d₁ of the cell may be of the order of 0.5 μm. In practice, a cell of the kind shown in FIG. 5a will have a number of portions which is larger than the five (80-84) shown. This will increase the quality of the spot produced by the cell.

The larger the number of phase steps in a diffraction cell is, the finer and brighter the spot that is produced by the cell. A limit to the number of phase steps may be imposed by the manufacturability of a diffraction element with such cells. The phase structure of the diffraction cell of FIG. 5 already approaches that of a Fresnel lens, shown in FIG. 5a. The similarity to the Fresnel lens increases with an increasing number of phase levels in the cell. An ideal spot will be obtained if the cell has an infinite number of phase steps, i.e. a cell having portion flanks continuously growing from 0° to 360°. Such a cell will remain a diffraction cell in view of its small outer dimensions of the order of 1 μm and even smaller portion area dimensions with respect to the wavelength of the imaging radiation.

Under circumstances, the number of phase steps in a diffraction cell may be less than four, for example three. In most cases, two amplitude levels in one diffraction cell will be sufficient, but under circumstances a diffraction cell may be provided with three or more amplitude levels.

The diffraction element with the multilevel phase structure can be manufactured by means of known lithographic techniques. For example, by means of an electron beam pattern generator, the cell pattern can be written in a resist, which is sensitive to electrons, and the different levels can be realized by selective ion etching. Also the so-called Canyon technique can be used. According to this technique an electron beam-sensitive glass, i.e. a glass which changes its transmission in dependence upon the electron beam intensity. The cell pattern is written in this glass as a grey pattern, i.e. amplitude pattern. Then, a three-dimensional cell pattern is formed in a resist layer, coated on a quartz substrate, using the grey pattern as a mask. By reactive ion etching, the resist pattern is transferred to the quartz substrate. After the mask substrate surface 70 has been provided with the multilevel phase structure, this surface is selectively coated with chromium to give the mask the required amplitude structure.

Instead of chromium, other non-transmission materials can be used for the selective coating of the mask. Instead of 100% transmission and 0% transmission for the amplitude levels, the mask may have different amplitude levels.

As demonstrated above, good results are obtained with a diffraction mask structure having two amplitude levels and four phase levels and diffraction cell dimensions of 1×1 μm². However, the mask structure for the above and other applications may have three or more than four phase levels and/or more than two amplitude levels and/or different dimensions for the diffraction cell areas. In general, it holds that levels the quality of the printed image will enhance with a decreasing cell area dimensions and an increasing number of amplitude and phase.

As shown in FIG. 3c, each spot 62 occupies only a small, point-like portion of the resist layer area belonging to the light valve which determines whether this spot is present or not. Hereinafter, the point-like resist areas will be called spot areas and the resist area belonging to a light valve will be called valve area. To obtain full features, i.e. lines and areas, of the image pattern corresponding to the device features to be produced, the substrate with the resist layer and the two arrays should be displaced relative to each other. In other words, each spot should be moved in its corresponding valve area such that this area is fully scanned and illuminated at prescribed, i.e. feature determined, positions. Most practically, this is realized by displacing the substrate stepwise in a grid-like pattern. The displacement steps are of the order of the size of the spots, for example of the order of 1 μm or smaller. A portion of the valve area belonging to a given spot, which portion is destined for an image feature or part thereof, is illuminated in flashes. For displacing the substrate holder in steps of 1 μm or smaller with the required accuracy, use can be made of servo-controlled substrate stages used in lithographic projection apparatuses and which operate with an accuracy of well below 1 μm, for example of the order of 100 nm.

The illumination process of flashing and stepping is illustrated in FIGS. 6a-6c, which show a small portion of the array of light valves, the diffraction element and the resist layer. In these Figures, the reference numeral 17 denotes the illuminating beam incident on the light valves 21-25. Reference numerals 101-105 denote the sub-beams passed by open light valves and converged by the corresponding diffraction cells 91-95. FIG. 6a presents the situation after a first sub-illumination has been made with all light valves open. A first set of spot areas 111-115, one spot area in each light valve area, has been illuminated. FIG. 6b presents the situation after the substrate has made one step to the right and a second sub-illumination has been made also with all light valves open. A second set of spot areas 121-125 has been illuminated. FIG. 6c presents the situation after the substrate has made five steps and six sub-illuminations have been made. During the fourth sub-illumination, light valves 23 and 25 were closed so that spot areas 133 and 135 have not been illuminated. During the fifth sub-illumination the light valves 24 and 25 were closed so that spot areas 144 and 145 have not been illuminated. All the other spot areas have been illuminated.

FIGS. 7a-7c show top views of the resist layer during subsequent sub-illumination steps. In these Figures, the dark spot areas have already been illuminated in preceding sub-illumination steps and the light spot areas are being illuminated in the present illumination step. The portion of the resist layer being illuminated comprises two rows of five light valve areas. In the situation depicted in FIG. 7a, a relatively large number of spot areas of the upper row and a lower number of spot areas in the lower row have already been illuminated. During a first sub-illumination, four of the five light valves belonging to the upper row of light valve areas are open and the fifth, the extreme right one, is closed so that spot areas 151-154 are momentarily illuminated and spot area 155 is not. All of the five light valves belonging to the lower row of light valve areas are open so that spot areas 156-160 are momentarily illuminated. FIG. 7b shows the situation after the substrate has made one step and a second sub-illumination is being carried out. Again four of the five light valves of the upper row are open and the fifth light valve of this row is closed so that spot areas 161-164 are momentarily illuminated and spot area 165 is not. All of the five light valves of the lower row are open so that spot areas 166-170 are momentarily illuminated. FIG. 7c shows the situation during the sixth sub-illumination, so after the substrate has made five steps. During the six sub-illumination the fifth light valve of the upper row was (is) closed. During the fourth sub-illumination, the third light valve of the upper row and the third and fourth light valve of the lower row were closed so that spot areas 181, 182 and 183 have not been illuminated. During the fifth sub-illumination, the fifth and sixth light valve of the lower row were closed so that spot areas 184 and 185 have not been illuminated. During the sixth sub-illumination, all light valves, except the sixth one of the upper row are open so that all spot areas 191-200 are momentarily illuminated, except spot area 195.

FIGS. 6a-6c and 7 a-7c show how ten light valve areas in the resist layer are simultaneously illuminated in successive steps of displacing the resist layer and opening and closing the ten corresponding light valves. The light valve areas of all light valves of the array are simultaneously illuminated in the same way. As shown in the upper right portion of FIG. 7a, scanning of a valve area 150 with a spot 62 can be performed serpentine wise. A first line of the area is scanned from left to right, a second line from right to left, a third line from left to right again, etc.

Instead of the stepping mode, illustrated in FIGS. 6a-6c and FIGS. 7a-7c, a scanning mode can be used to produce the required image pattern. In the scanning mode, the resist layer and the arrays of light valves and diffraction cells are continuously moved with respect to each other and the light valves are flashed when they face a prescribed position on the resist layer. The flash time, i.e. the open-time of the light valve, should be smaller than the time during which the relevant light valve faces said position. As a consequence, the intensity of the illumination beam and the switching frequency of the light valve array for the scanning mode should be larger than for the stepping mode.

In a practical embodiment of the proximity printing apparatus shown in FIG. 2, the several parameters have the following values:

| | |
|---|---|
| Illuminated field: | 10 × 10 mm²; |
| Radiation source: | Mercury-arc lamp; |
| Intensity of the illumination beam: | 20 mW/cm²; |
| Beam collimating angle: | 0.5 degrees; |
| Transmission of the light valves: | 50%; |
| Shutter speed of the light valves: | 1 ms.; |
| Size of the spots in the resist layer: | 1 × 1 μm²; |
| Spot-to-spot distance: | 100 μm; |
| Number of light valves; | 1.000.000; |
| Intensity of the spots: | 100 W/cm²; |
| Exposure dose; | 100 mJ/cm²; |
| Total exposure time: | 10 sec.; |
| Gap width: | 100 μm |
| Scan speed: | 1 mm/sec. |

The exposure dose is the amount of illumination radiation energy in a spot area of the resist. The intensity of the illumination beam and the opening time of the light valve determine this dose.

The mercury arc discharge lamp emits radiation, 40% of which has a wavelength of 365 nm, 20% has a wavelength of 405 nm and 40% has a wavelength of 436 nm. The effective contribution to the image formation of this lamp radiation is 60% by the 365 nm component, 15% by the 405 nm component and 25% by the 436 nm component due to the absorption in the resist layer. A general problem with diffraction elements is that their performance is wavelength-dependent. For the present method and apparatus, this means that beam components of the mercury arc lamp with different wavelengths would be focused in different planes. However, in the case where somewhat broader spots are allowed, some freedom of design of the diffraction cells remains. This freedom can be used to correct the wavelength dependence and to design the diffraction cells in such a way that the beam components with different wavelengths will be focused in the same plane. This allows use of the mercury arc discharge lamp, which has proved its benefits for conventional proximity printing, also in the new method and apparatus.

Nevertheless, it is preferred to use a monochromatic source, for example a YAG laser emitting radiation at a wavelength of 350 nm, because no wavelength corrections are needed.

The invention can also be implemented with other radiation sources, preferably lasers, especially lasers used currently or to be used in the near future in wafer steppers and wafer step-and-scanners, emitting radiation at wavelengths of 248, 193 and 157 nm, respectively. Lasers provide the advantage that they emit a beam, which is collimated to the required degree. Essential for the present imaging method is that the illumination beam is substantially a collimated beam. The best results are obtained with a fully collimated beam, i.e. a beam having an aperture angle of 0°. However, satisfactory results can also be obtained with a beam having an aperture angle smaller than 1°.

The required movement with respect to each other of the resist layer, on the one hand, and the array of light valves and the diffraction element, on the other hand, is most practically performed by movement of the substrate stage. Substrate stages currently used in wafer steppers are very suitable for this purpose, because they are more than accurate enough. It will be clear that movement of the substrate stage, for either the stepping mode or the scanning mode, should be synchronized with the switching of the light valve. To that end, the stage movement may be controlled by the computer, 30 in FIG. 2 which controls the light valve array.

An image pattern which is larger than the illumination field of one array of light valves and one array of diffraction cells can be produced by dividing, in the software, such a pattern into sub-patterns and successively transferring the sub-patterns to neighboring resist areas having the size of the image field. By using an accurate substrate stage, the sub-image patterns can be put together precisely so that one non-interrupted large image is obtained.

A large image pattern can also be produced by using a composed light valve array and a composed diffraction cell array. The composed light valve array comprises, for example, five LCDs, each having 1000×1000 light valves. The LCDs are arranged in a series to cover, for example, the width of the image pattern to be produced. The composed diffraction element is constructed in a corresponding way to fit to the composed light valve array. The image pattern is produced by first scanning and illuminating a resist area having a length covered by a single array of light valves and a width covered by the series of light valve arrays. Subsequently, the substrate with the resist layer and the series of arrays are displaced relative to each other in the longitudinal direction through a distance covered by a single array. A second resist area, which now faces the composed arrays is scanned and illuminated, etc until the whole image pattern has been produced.

An essential parameter for the imaging process is the gap width 44 (FIG. 2). Gap width is one of the input parameters for computing the diffraction element structure and is determined by the required image resolution. If a diffraction element structure is computed and manufactured for a given gap width and resolution, this resolution can only be obtained for the given gap width. If, in real circumstances, the gap width deviates from said given gap width, the required resolution cannot be achieved. This is demonstrated in FIGS. 8a, 8b and 8c. These Figures show the spots formed in the resist layer by means of the same diffraction element, designed for a gap width of 50 μm, and under the same illumination conditions, but with different gap widths. FIG. 8a shows a pattern 210 of spots 62′ obtained with a gap width of 40 μm, FIG. 8b shows a pattern 220 of spots 62 obtained with a gap width of 50 μm and FIG. 8c shows a pattern 230 of spots 62″ obtained with a gap width of 60 μm. It will be clear from these Figures that only the spots obtained with a gap width which is equal to the design gap width have the required sharpness and intensity.

For an apparatus with a larger design gap width, for example 250 μm, the requirements for the real gap width can be mitigated. With an increasing design gap width, the NA of the sub-beams (101-105 in FIG. 6a) from the diffraction cells decreases. As the depth of focus is proportional to the inverse of the squared NA, the depth of focus increases with an increasing design gap width. This means that, for a larger design gap width, larger gap width variations are tolerable than for a smaller design gap width. From a tolerance point of view, a larger gap width, for example 250 μm, is preferred to a smaller gap width, for example 50 μm.

The minimum size of the spots is also related to the gap width. If the gap width is reduced, this size can be decreased, for example below 1 μm. A smaller gap width requires a better control of this width.

A feature of the present diffraction element is that it allows the creation of multiple focal planes within a single image field. The outlay of this diffraction elements allows its design, or computation on a cell-by-cell basis, in which the distance between the diffraction element and the resist layer, or the focal distance, may be taken as one of the input parameters. This allows design of a diffraction element wherein one or more area(s), comprising a number of diffraction cells, is (are) intended for a different focal distance than the remaining portion of the diffraction element. This multiple focal diffraction element can be used for the manufacture of a device composed of sub-devices positioned at different levels. Such a device may be a pure electronic device or a device that comprises two or more different kinds of features from the range of electrical, mechanical or optical systems. An example of such a system is a micro-optical-electrical-mechanical (MOEM) module or a device comprising a diode laser or a detector and a light guide and possibly lens means to couple light from the laser into the light guide or from the light guide to the detector. The lens means may be planar diffraction means. For the manufacture of a multilevel device, a substrate is used that has a resist layer deposited on different levels. By using a multiple focal diffraction element, all sub-images can be printed simultaneously on the relevant levels, so that a lot of time can be saved.

A multiple diffraction element can only be used for the production of a device showing the multiple level structure corresponding to the multiple focus structure of the diffraction element. The imaging apparatus may, however, be designed, in such a way that diffraction elements can easily be placed in and removed from the apparatus. This allows production of different multiple level devices by means of different appropriate multiple focus diffraction elements.

Multiple level devices can also be produced by means of a general, single focus, diffraction element. In the software, the total image pattern is divided into a number of sub-images each belonging to a different level of the device to be produced. In a first sub-imaging process, the first sub-image is produced, with the resist layer being positioned at a first level. The first sub-imaging process is performed according to the, scanning or stepping, method and by the means described hereinbefore. Then the resist layer is positioned at a second level, and in a second sub-imaging process the sub-image belonging to the second level is produced. The shifts of the resist layer in the Z-direction and the sub-imaging processes are repeated until all sub-images of the multiple level device are transferred to the resist layer.

The method of the invention can be carried out with a robust apparatus that is, moreover, quite simple as compared with a stepper or step-and-scan lithographic projection apparatus.

In the apparatus, schematically shown in FIG. 2, the array of light shutters 21-25, i.e. a LCD, is arranged as close as possible to the diffraction element comprising the array of diffraction cells 91-95. The size of the light valves, or pixels, of this LCD may be relatively large, for example 100×100 μm². In a LCD device, a polarization analyzer, also called analyzer, is needed to convert polarization states, introduced by the light valves, into intensities. If a commercially available LCD panel, currently applied in video projectors working with visible light, is used, the visible light analyzer should be removed from the panel and a separate UV or DUV analyzer should be arranged between the light valves and the diffraction element. Moreover, the substrate 41 of the diffraction element 40 has some thickness. As a consequence, there is some distance between the light valves and the diffraction cells of the diffraction element. This distance should be taken into account when designing the apparatus in order to prevent a non-sharp image of the light valves from being formed on the diffraction cells and crosstalk occurring between light valves due to said distance and diffraction effects.

To reduce the distance between the light valves and the diffraction cells and to prevent annoying crosstalk, the diffraction element may be arranged on the lower surface of the polarizer and/or the polarizer may be arranged on the light valve structure.

FIG. 9 shows an alternative embodiment of the apparatus, which is attractive in view of the above remarks. This apparatus comprises a projection lens, which images the array of light valves on the array of diffraction elements, wherein each light valve is conjugated with a corresponding diffraction cell. The use of a projection lens allows more freedom of design than allowed in the sandwich design of the FIG. 2 apparatus.

The left part of FIG. 9 shows an illumination system, which my also be used in the apparatus of FIG. 2. This illumination system comprises a radiation source, for example a mercury lamp 13 and a reflector 15, which may have the shape of a half sphere. The reflector may be arranged with respect to the lamp, such that no central obstruction of the illumination beam occurs. Lamp 13 and reflector 15 may be replaced by a laser. The beam from the radiation source 13,15 is incident on a wavelength-selective reflector or dichroic mirror 246, which reflects only the beam component with the required wavelength, for example UV or DUV radiation, and removes radiation of other wavelengths, such as IR or visible radiation. If the radiation source is a laser, no selective reflector is needed and either a neutral reflector can be arranged at the position of the reflector 246 or the laser can be arranged in line with the rest of the optical path. A first condenser lens system, for example comprising a first condenser lens 247 and a second condenser lens 248 arranged before and after the reflector 246, respectively, converges the illumination beam 17 on a radiation shutter 252. This shutter is provided with a diaphragm 253, which shape determines the shape of the spots formed in the resist layer 5. A second condenser system, for example comprising condenser lenses 254,255 concentrates the radiation passed by diaphragm 253 in the pupil 261, or diaphragm, of a projection lens 260, i.e. it images diaphragm 253 in the plane of the pupil of the projection lens 260. The beam passing condenser lens 255 illuminates LCD 20, which is arranged between condenser lens 255 and projection lens 260. This lens images the LCD on diffraction element 40, described hereinbefore, such that each light valve (pixel) of the LCD is conjugated with a corresponding diffraction cell of the diffraction element. If a light valve is open, the radiation from this valve is incident on the conjugated diffraction cell only. The diffraction element may be arranged at a distance of 600 mm from the LCD. The distance between the diffraction element and the resist layer 1 may be of the order of 100-300 μm.

The LCD 20 may have a pixel size of 20 μm and the projection lens may image the LCD pixel structure on the diffraction element with a magnification of 5×. For such imaging, no large numerical aperture (NA) for the projection lens is required. To achieve that the illumination beam incident on the diffraction element is a parallel beam, a collimator lens 262 is arranged in front of the diffraction element. For example, a diaphragm opening of 1 mm will be imaged by the projection lens and a diffraction cell in a spot with a dimension of 1 μm. As the operation of the LCD is based on changing the polarization state of incident radiation, a polarizer, which gives the radiation the required initial polarization state, and a polarization analyzer, which converts the polarization state into an intensity, are needed. This polarizer and analyzer are denoted by reference numerals 250 and 258, respectively The polarizer and analyzer are adapted to the wavelength of the illumination beam. They are not shown in FIG. 2, but a polarizer and analyzer are also present in the apparatus according to this Figure.

As the image of the LCD pixel structure is focused on the diffraction element, practically no crosstalk will occur in an apparatus with a projection lens. Moreover, the diffraction element may comprise a thick substrate so that it is more stable. When in use, a LCD shutter array absorbs radiation and produces heat, which may cause thermal effects in the apparatus. Such effects are considerably reduced in an apparatus with a projection lens, because the LCD is arranged at a relatively large distance from the diffraction element. Moreover, the design allows separate cooling of the LCD. A LCD light valve array may comprise spacers in the form of small, for example 4 μm, spheres of a polymer material. Such spheres may cause optical disturbances. In an apparatus with a projection lens, the effects of the spacers are reduced because the projection lens with a relatively small NA functions as a spatial filter for the high-frequency disturbances.

When using a projection lens, it will be easy to replace a transmission light valve array by a reflective array, such as a reflective LCD or a digital mirror device.

The apparatus of FIG. 9 is only one example of an apparatus with a projection lens. Many modifications of the FIG. 9 apparatus are possible.

In practice, the method of the invention will be applied as one step in a process for manufacturing a device having device features in at least one process layer of a substrate. After the image has been printed in the resist layer on top of the process layer, material is removed from, or added to, areas of the process layer which areas are delineated by the printed image. These process steps of imaging and material removing or adding are repeated for all process layers until the whole device is finished. In those cases where sub-devices are to be formed at different levels and use can be made of multiple level substrates, a multiple focal diffraction element can be used for image printing.

The invention can be used for printing patterns of, and thus for manufacturing display devices like LCD, Plasma Display Panels and PolyLed Displays, printed circuit boards (PCB) and micro-multiple function systems (MOEMS).

1. A method of forming an optical image in a resist layer, the method comprising the steps of:
providing a radiation source;
providing a resist layer;
positioning a two-dimensional array of individually controlled light valves between the radiation source and the resist layer;
positioning a two-dimensional array of diffraction lenses between the array of light valves and the resist layer, such that each diffraction lens corresponds to a different one of the light valves;
successively illuminating different portions of the resist layer by means of successive sub-illuminations, each sub-illumination comprising the steps of switching on a selection of the light valves, switching on the radiation source, switching off the light valves and the radiation source and displacing the resist layer and the arrays relative to each other so that a subsequent layer portion to be illuminated is aligned with the arrays, characterized in that use is made of diffraction lenses in the form of identical diffraction cells having at least two transmission levels and at least three phase levels.

2. A method as claimed in claim 1, characterized in that use is made of an array of diffraction cells, each showing a series of rising phase steps and a series of declining phase steps.

3. A method as claimed in claim 1, characterized in that use is made of an array of diffraction cells, each comprising a number of successive phase structures, each phase structure comprising a number of phase steps rising from a base level to a top level followed by a decline from the top level to the base level.

4. A method as claimed in claim 1, characterized in that use is made of an array of diffraction cells each comprising a number of successive phase structures, each phase structure showing a continuous increase from a base level to a top level and an abrupt decline from the top level to the base level.

5. A method as recited in claim 1 wherein, use is made of an array comprising collections of diffraction cells, which collections differ from each other in that the focal plane of the diffraction cells of each collection is different from the focal planes of the other collections.

6. A method as recited in claim 1 wherein, between successive sub-illuminations, the radiation-sensitive layer and the arrays are displaced relative to each other through a distance which is at most equal to the size of the spots formed in the resist layer.

7. A method as recited in claim 1 wherein, the intensity of a spot at the border of an image feature is adapted to the distance between this feature border and a neighboring feature.

8. A method as recited in claim 1 wherein, the illumination step comprises illuminating the array with a beam of monochromatic radiation.

9. A method as recited in claim 1 wherein, the array of light valves is positioned to directly face the array of diffraction cells.

10. A method as recited in claim 1 wherein, the array of light valves is imaged on the array of diffraction cells.

11. A diffraction element for use with the method as recited in claim 1, and comprising an array of diffraction cells, characterized in that the diffraction cells have at least two amplitude levels and at least three phase levels.

12. A diffraction element recited in claim 11 wherein, each diffraction cell has a series of rising phase steps and a series of declining phase steps.

13. A diffraction element as recited in claim 12 wherein, the diffraction cells have four phase levels, which differ from each other by 90°.

14. A diffraction element as as recited in claim 12 wherein, each diffraction cell comprises a number of successive phase structures, each phase structure comprising a number of phase steps rising from a base level to a top level followed by a decline from the top level to the base level.

15. A diffraction element as recited in claim 11 wherein, each diffraction cell comprises a number of successive phase structures, each phase structure showing a continuous increase from a base level to a top level and an abrupt decline from the top level to the base level.

16. A diffraction element as as recited in claim 11 wherein, the diffraction element comprises collections of diffraction cells, which collections differ from each other in that the focal plane of the diffraction cells of each collection is different from the focal planes of the other collections.

17. An apparatus for carrying out the method as claimed in claim 1, the apparatus comprising:
a radiation source;
a substrate holder for holding a substrate provided with a resist layer;
a two-dimensional array of individually controllable light valves arranged between the source and the substrate holder, and
a diffraction element comprising a two-dimensional array of diffraction lenses arranged between the array of light valves and the substrate holder, such that each diffraction lens corresponds to a different one of the light valves, characterized in that diffraction lenses are diffraction cells having at least two amplitude levels and at least three phase levels.

18. An apparatus as claimed in claim 17, characterized in that each diffraction cell has a series of rising phase steps and a series of declining phase steps.

19. An apparatus as claimed in claim 18, characterized in that the diffraction cells have four phase levels, which differ from each other by 90°.

20. An apparatus as claimed in claim 17, characterized in that each diffraction cell comprises a number of successive phase structures, each phase structure comprising a number of phase steps rising from a base level to a top level followed by a decline from the top level to the base level.

21. An apparatus claimed in claim 17, characterized in that each diffraction cell comprises a number of successive phase structures, each phase structure showing a continuous increase from a base level to a top level and an abrupt decline from the top level to the base level.

22. An apparatus as recited in claim 17 wherein, the diffraction element comprises collections of diffraction cells, which collections differ from each other in that the focal plane of the diffraction cells of each collection is different from the focal planes of the other collections.

23. An apparatus as recited in claim 17 wherein, the radiation source is a source of monochromatic radiation.

24. An apparatus as recited in claim 17 wherein, the diffraction element is arranged behind the array of light valves without intervening imaging elements.

25. An apparatus as recited in claim 17 wherein, a projection lens is arranged between the array of light valves and the diffraction element.

26. An apparatus as claimed in claim 24, characterized in that the distance between surface of the diffraction element carrying the diffraction structure and the resist layer is of the order of 250 μm.

27. A method of manufacturing a device in at least one process layer of a substrate, the method comprising the steps of:
forming an image, comprising features corresponding to device features to be configured in the process layer, in a resist layer provided on the process layer, and
removing material from, or adding material to, areas of said process layer, which areas are delineated by the image formed in the resist layer, characterized in that the image is formed by means of the method as claimed in any one of claims 1 to 10.
